(19) United States
(12) Patent Application Publication
(10) Pub. No.: US 2023/0046911 A1
(43) Pub. Date: Feb. 16, 2023

(54) BACKSIDE INTERCONNECT STRUCTURES IN INTEGRATED CIRCUIT CHIPS

(71) Applicant: Taiwan Semiconductor Manufacturing Co., Ltd., Hsinchu (TW)

(72) Inventors: Meng-Han WANG, Hsinchu (TW); Yu-Ting LIN, Hsin-Chu City (TW); Chia Hong LIN, Hsinchu (TW); Wei-Cheng LIU, Hsinchu (TW)

(73) Assignee: Taiwan Semiconductor Manufacturing Co., Ltd., Hsinchu (TW)

(21) Appl. No.: 17/852,594

(22) Filed: Jun. 29, 2022

Related U.S. Application Data
(60) Provisional application No. 63/231,842, filed on Aug. 11, 2021.

(51) Int. Cl. H01L 23/528; G06F 30/392

(52) U.S. Cl. CPC H01L 23/528; G06F 30/392

(57) ABSTRACT

The present disclosure describes a structure that includes a substrate with first and second sides, a device layer disposed on the first side of the substrate, having a fault detection area on a back-side surface of the device layer configured to emit a signal that is indicative of a presence or an absence of a defect in the device layer, a first interconnect structure disposed on a front-side of the device layer, and a second interconnect structure disposed on the second side of the substrate, having a metal-free region aligned with the fault detection area and a first metal layer having first and second conductive lines disposed substantially parallel to each other. First and second sidewalls of the first and second conductive lines, respectively, facing each other are substantially aligned with first and second sides of the fault detection area.

### CROSS-REFERENCE TO RELATED APPLICATIONS

The present application claims the benefit of U.S. Provisional Patent Appl. No. 63/231,842, titled “Backside Conductive Lines and Methods for Forming the Same” and filed on Aug. 11, 2021, which is incorporated herein by reference in its entirety.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs, fin field effect transistors (finFETs), and gate-all-around (GAA) FETs in integrated circuit (IC) chips. Such scaling down has increased the complexity of manufacturing the IC chips and the complexity of fault detection in the manufactured IC chips.

### BRIEF DESCRIPTION OF THE DRAWINGS

Aspects of the present disclosure are best understood from the following detailed description when read with the accompanying figures. It is noted that, in accordance with common practice in the industry, various features are not drawn to scale. In fact, the dimensions of the various features may be arbitrarily increased or reduced for clarity of discussion.

FIG. 1 is a cross-sectional view of an IC chip package without keep-out regions in a back-side interconnect structure, according to some embodiments.

FIG. 2A is a cross-sectional view of an IC chip package having keep-out regions in a back-side interconnect structure, according to some embodiments.

FIGS. 2B-2D are standard cell circuits in an IC chip package, in accordance with some embodiments

FIG. 3 is a flow diagram of a method for forming keep-out regions and placing conductive lines in a back-side interconnect structure, according to some embodiments.

FIG. 4 is a schematic illustration of arrays of standard cells, according to some embodiments.

FIG. 5 is a schematic illustration of a circuit layout in a standard cell, according to some embodiments.

FIGS. 6A-6B and 7 are schematic illustrations of circuit layouts with keep-out regions in a back-side interconnect structure, according to some embodiments.

FIG. 8 is an illustration of an exemplary computer system for implementing various embodiments of the present disclosure, according to some embodiments.

FIG. 9 is an illustration of a process to form standard cell structures and conductive line placement and routing based on a graphic database system (GDS) file, according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed that are between the first and second features, such that the first and second features are not in direct contact. In addition, the present disclosure may repeat reference numerals and/or letters in the various examples. This repetition does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “nominal” as used herein refers to a desired, or target, value of a characteristic or parameter for a component or a process operation, set during the design phase of a product or a process, together with a range of values above and/or below the desired value. The range of values can be due to slight variations in manufacturing processes or tolerances.

The term “vertical,” as used herein, means nominally perpendicular to the surface of a substrate.

In some embodiments, the terms “about” and “substantially” can indicate a value of a given quantity that varies within 20% of the value (e.g., ±1%, ±2%, ±3%, ±4%, ±5%, ±10%, ±20% of the value). These values are merely examples and are not intended to be limiting. The terms “about” and “substantially” can refer to a percentage of the values as interpreted by those skilled in relevant art(s) in light of the teachings herein.

An integrated circuit (“IC”) chip can include a compilation of layers with different functionality, such as interconnect structures, power distribution network, logic chips, memory chips, radio frequency (RF) chips, and the like. The IC chip can be coupled to a back-side interconnect structure in addition to a front-side interconnect structure to improve device density and manufacturing flexibility. For example, the back-side interconnect structure can include a power distribution network formed on a back-side surface of the IC chip and can be electrically connected to back-sides of semiconductor devices (e.g., back-sides of source/drain regions and/or back-sides of gate structures) of the IC chip to supply power to the semiconductor devices. The back-side interconnect structure can include multiple layers of metal conductive lines connected by vias and can transmit power to various regions of the IC chip.

The IC chip is subject to variations in the manufacturing process that can result in latent fabrication defects in the electrical components of the IC chip. When fabrication conditions in the processing chamber deviate from the ideal conditions, abnormalities can be introduced in the physical structure of the electrical components that manifest as faults in the operation of the IC chip. A fault detection system can be used to detect the faults and provide real-time results on fabrication yield or operation status of the semiconductor devices in the IC chip.

An exemplary fault detection system includes a detector or sensor that is placed under an IC chip package and configured to detect optical signals generated at semiconductor device areas corresponding to output terminals (e.g., source/drain terminals) of standard cell circuits in the IC chip. The optical signals can propagate through semiconductor materials (e.g., a semiconductor substrate) in the IC chip and dielectric materials (e.g., interlayer dielectric (ILD) layers) in the back-side interconnect structure and emit from the back-side of the IC chip package. The detector can be configured to capture and analyze the emitted signals. In some embodiments, the fault detection system can identify one or more malfunctioning standard cells of the IC chip based on the analyzed signal. However, signals emitted by the semiconductor devices can be blocked or hampered by metal elements (e.g., metal lines or metal vias) in back-side interconnect structure, impacting real-time fault detection in IC chip.

Various embodiments described in the present disclosure are directed to back-side interconnect structures in IC chip packages and methods for forming the same. In some embodiments, the back-side interconnect structure can include metal lines, metal vias, and metal-free regions (also referred to as “keep-out regions”). The metal-free regions can be formed substantially aligned with output terminals of standard cell circuits in the IC chip to prevent optical signals from being blocked by metal elements in the back-side interconnect structures during the fault detection in the IC chip. In some embodiments, an automatic placement and routing (APR) tool can be configured to scan standard cell circuit layouts of the IC chip to identify active areas corresponding to output terminals of the standard cell circuits and design metal-free regions in the metal layout of the back-side interconnect structure. According to one or more routing and placement rules, no conductive line of the back-side interconnect structure is formed in the metal-free regions which in turn allows signals emitted by the one or more active areas to be transmitted through the back-side interconnect structure and detected by sensors of the fault detection system.

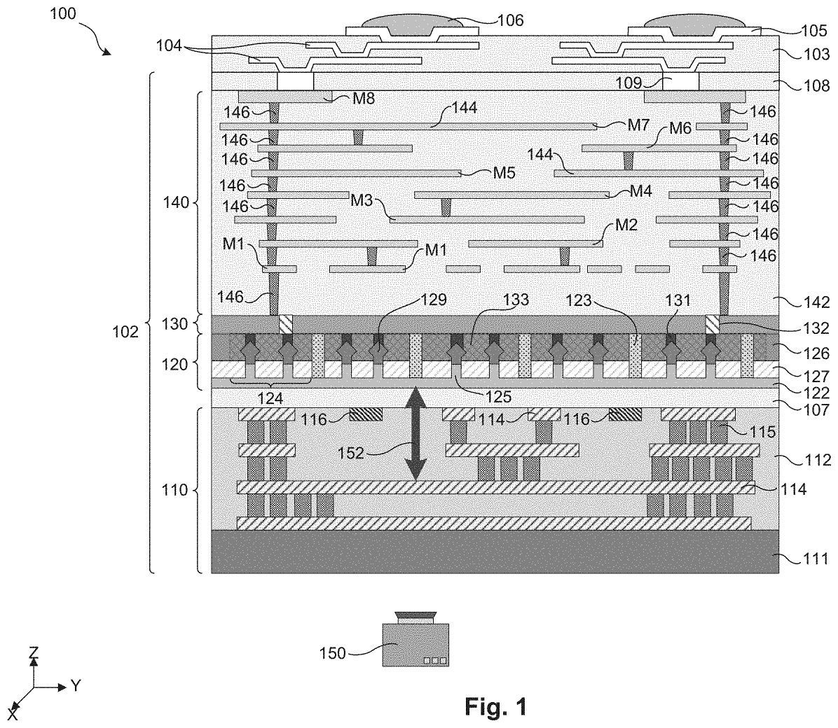

FIG. 1 is a cross-sectional view of an IC chip package 100 incorporating a back-side interconnect structure without a keep-out regions, according to some embodiments. In some embodiments, IC chip package 100 can have an integrated fan-out (InFO) package structure. In some embodiments, IC chip package 100 can include (i) an IC chip 102, (ii) a dielectric layer 103 disposed on a front-side surface of IC chip 102, (iii) redistribution layers (RDLs) 104 disposed in dielectric layer 103, (iv) metal contact pads 105 disposed on dielectric layer 103 and in electrical contact with RDLs 104, and (v) conductive bonding structures 106 disposed on metal contact pads 105. In some embodiments, IC chip package 100 can include other elements, such as molding layer surrounding IC chip 102 and conductive through-vias disposed in the molding layer and adjacent to IC chip 102, which are not shown for simplicity.

In some embodiments, RDLs 104 can be electrically connected to semiconductor devices of device region 120 (discussed below) of IC chip 102. RDLs 104 can be configured to fan out IC chip 102 such that I/O connections (not shown) on IC chip 102 can be redistributed to a greater area than IC chip 102, and consequently increase the number of I/O connections of IC chip 102. In some embodiments, conductive bonding structures 106 can be electrically connected to RDLs 104 through metal contact pads 105. In some embodiments, conductive bonding structures 106 can electrically connect IC chip package 100 to a printed circuit board (PCB). In some embodiments, RDLs 104 and metal contact pads 108 can include a metal (such as copper and aluminum), a metal alloy (such as copper alloy and aluminum alloy), or a combination thereof.

In some embodiments, IC chip 102 can include (i) a device region 120, (ii) a back-side contact region 107 including conductive structures (not shown) in a dielectric layer disposed on a back-side surface of device region 120, (iii) a back-side interconnect structure 110 disposed on a back-side surface of back-side contact region 107, (iv) a substrate 111 disposed on back-side surface of back-side interconnect structure 110, (v) a front-side contact region 130 including via structures 132 in a dielectric layer disposed on a front-side surface of device region 120, (vi) a front-side interconnect structure 140 disposed on front-side contact region 130, (vii) a passivation layer 108 disposed on front-side interconnect structure 140, and (viii) conductive pads 109 disposed within passivation layer 108 and on front-side interconnect structure 140. IC chip 102 can further include other suitable structures and are not illustrated in FIG. 1 for simplicity. Components in IC chip 102 are for illustration purposes and are not drawn to scale.

Device region 120 can include a substrate 122 and semiconductor devices 124 formed on substrate 122. In some embodiments, device region 120 can further include isolation structures 123 disposed between semiconductor devices 124. In some embodiments, device region 120 can be referred to as “a front-end-of-line (FEOL)” region of a semiconductor structure. Substrate 122 can be a p-type substrate, such as a silicon material doped with a p-type dopant (e.g., boron). In some embodiments, substrate 122 can be an n-type substrate, such as a silicon material doped with an n-type dopant (e.g., phosphorous or arsenic). In some embodiments, substrate 122 can include, germanium, diamond, a compound semiconductor, an alloy semiconductor, a silicon-on-insulator (SOI) structure, any other suitable material, or combinations thereof. Substrate 122 can include sensor devices, transistors, an application-specific integrated circuit (ASIC), a field programmable gate array (FPGA), a memory device, a microelectromechanical system (MEMS), any suitable device, or any combination thereof.

In some embodiments, semiconductor devices 124 can include passive/active devices, such as capacitors, inductors, and/or transistors, arranged to be CMOS circuits, RF circuitry, logic circuits, peripheral circuitry, and the like. In some embodiments, each of semiconductor devices 124 can include finFETs or GAA FETs, which can include (i) fin structures 125, (ii) shallow trench isolation (STI) regions 127 disposed between fin structures 125, (iii) source/drain (S/D) regions 129 disposed on fin structures 125, (iv) ILD layer 126 disposed on S/D regions 129, (v) front-side S/D contact structures 131, and (vi) gate structures 133 disposed on fin structures 125. In some embodiments, semiconductor devices 124 can be planar transistor devices. In some embodiments, gate structures 133 in GAA FETs can be GAA structures (not shown), which can be surrounded around nanostructured channel regions (not shown) disposed on fin structures 125.

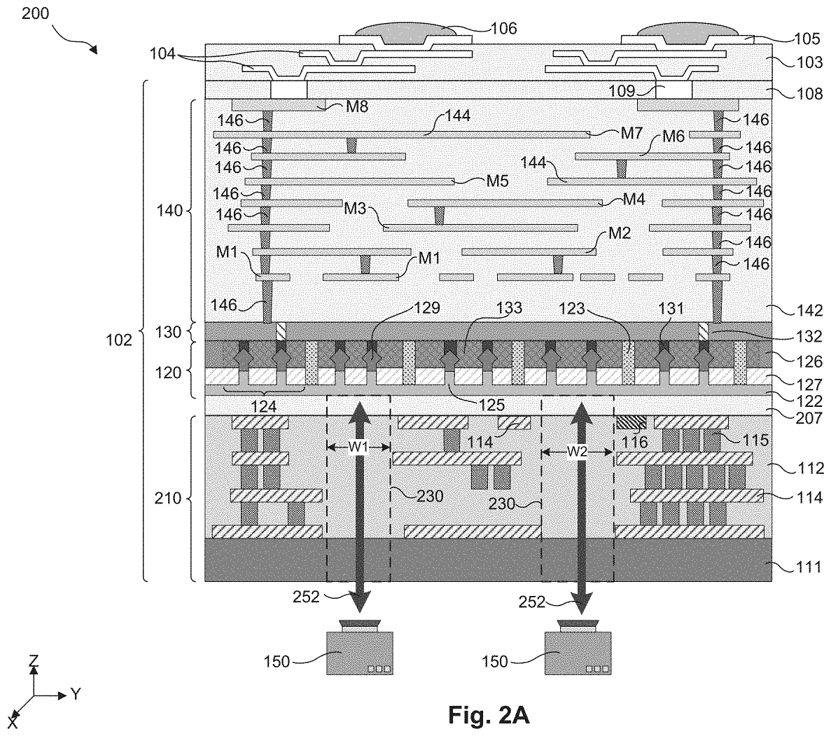

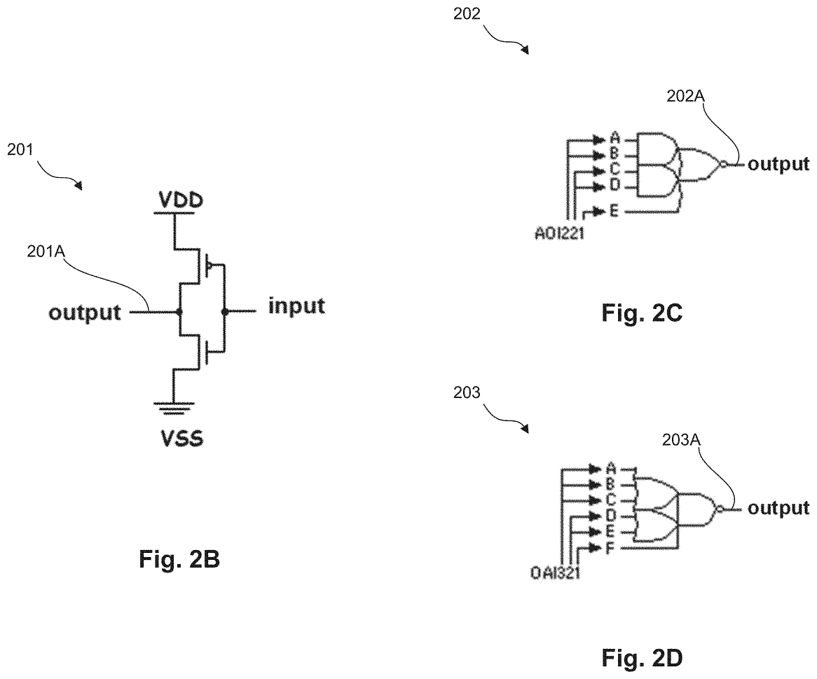

In some embodiments, semiconductor devices 124 can be electrically connected to back-side interconnect structure 110 through conductive structures (not shown) in back-side contact region 107 and can be can be electrically connected to RDLs 104 through front-side interconnect structure 140 and conductive pads 109. In some embodiments, semiconductor devices 124 can form a standard cell circuit 201, 202, and/or 203 as shown in FIGS. 2B, 2C, and 2D, respectively. In some embodiments, standard cell circuits 201-203 can include output terminals 201A-203A, respectively. In some embodiments, output terminals 201A-203A can be S/D contact structures of semiconductor devices 124 (e.g., front-side S/D contact structures 131 shown in FIG. 1). In some embodiments, the operation status and/or manufacturing yield of semiconductor devices 124 in standard cell circuit 201, 202, and/or 203 can be determined and monitored by a fault detection system based on the optical signals from S/D regions 129 corresponding to output terminals 201A-203A, as described in detail below with reference to FIG. 2A.

Backside interconnect structure 110 can be a power distribution network (PDN) disposed on back-side of device region 120. Back-side interconnect structure 110 can be electrically connected to back-side surfaces of semiconductor devices 124 (e.g., back-side surfaces of S/D regions 129 and/or back-side surfaces of gate structures 133) in device region 120 through conductive structures in back-side contact region 107 and/or other suitable conductive structures to supply power to semiconductor devices 124. Back-side interconnect structure 110 can include power grid (PG) wires, such as conductive lines 114 and 116, embedded in a back-side dielectric layer 112. Backside interconnect structure 110 can further include conductive vias 115 to provide electrical connection between the PG wires. In some embodiments, conductive lines 114 and 116 can be electrically connected to the same voltage level, such as V_{SS} (e.g., ground voltage reference) or V_{DD} (e.g., power supply voltage reference) of integrated circuit power supply lines. In some embodiments, conductive lines 114 and 116 can be electrically connected to different voltage sources. For example conductive lines 114 can be connected to V_{DD}, and conductive lines 116 can be connected to V_{SS}.

In some embodiments, conductive lines 114 and 116 can be formed of conductive materials, such as copper, aluminum, cobalt, tungsten, metal silicides, highly-conductive tantalum nitride, any suitable conductive materials, and/or combinations thereof. In some embodiments, PG wires, such as conductive lines 114 and 116, can extend in a horizontal direction (e.g., x or y direction). In some embodiments, back-side dielectric layer 112 can include dielectric materials, such as silicon oxide, undoped silica glass, fluorinated silica glass, and other suitable materials. In some embodiments, back-side dielectric layer 136 can include a low-k dielectric material (e.g., material with a dielectric constant less than 3.9). In some embodiments, conductive vias 115 can be formed of a conductive material, such as copper, aluminum, cobalt, tungsten, any suitable conductive material, and/or combinations thereof. In some embodiments, back-side vias 115 can be formed using a damascene process. The layout of conductive lines 114 and 116 and vias 115 is exemplary and not limiting and other layout variations of conductive lines 114 and 116 and vias 115 are within the scope of this disclosure. The number and arrangement of conductive lines 114 and 116 and vias 115 can be different from the ones shown in FIG. 1. The routings (also referred to as “electrical connections”) between device region 120 and back-side interconnect structure 110 are exemplary and not limiting. There may be routings between device layer 120 and back-side interconnect structure 110 that are not visible in the cross-sectional view of FIG. 1.

Front-side contact region 130 can be formed over device region 120 and can include via structures 132 for electrically connecting semiconductor devices 124 to front-side interconnect structure 140. Front-side contact region 130 can be referred to as “a middle-of-the-line (MEOL)” region of a semiconductor structure. Additional suitable contacts can be formed in contact region 130 and are not illustrated in FIG. 1 for simplicity.

Front-side interconnect structure 140 can include metal lines 144 and vias 146 embedded in one or more ILD layers 142. Metal lines 144 and vias 146 can electrically couple device region 130 to external circuitry. In some embodiments, metal lines 144 and vias 146 can be formed of various suitable metal materials. In some embodiments, front-side interconnect structure 140 can be referred to as “a back-end-of-line (BEOL)” structure of a semiconductor structure.

ILD layers 142 can be formed on contact region 130 and can include one or more dielectric materials. In some embodiments, the dielectric materials can include silicon oxide, silicon nitride, silicon oxynitride, spin-on glass (SOG), fluorinated silica glass (FSG), carbon doped silicon oxide (e.g., SiCOH), amorphous fluorinated carbon, Parylene, bis-benzocyclobutenes, polyimide, other proper porous polymeric materials, other suitable dielectric materials, and/or combinations thereof. In some embodiments, ILD layers 142 can include a high density plasma (HDP) dielectric material (e.g., HDP oxide) and/or a high aspect ratio process (HARP) dielectric material (e.g., HARP oxide). ILD layers 142 can include multiple layers; for example, different interlayer dielectric layers can be used to provide physical and electrical isolation between metal lines 144 and vias 146. The multiple interlayer dielectric layers in ILD layers 142 are not illustrated in FIG. 1 for simplicity.

In some embodiments, front-side interconnect structure 140 can include metal line layers M1-M8 including metal lines 144 and vias 146 providing electrical connection between metal line layers M1-M8. For example, metal line layer M1 can be a first metallization layer that is connected to terminals of semiconductor devices 124 through front-side S/D contact structures 131 and via structures 132 disposed in front-side contact region 130. Metal line layer M2 can be a second metallization layer that is above metal line layer M1 and electrically connected to metal line layer M1 through vias 146. Metal line layers M3-M8 can be metallization lines subsequently formed in ILD layer 142 that are electrically connected to transmit power and/or signals. Vias 146 can be formed in ILD layer 142 using conductive material, such as copper, silver, tungsten, aluminum, cobalt, any suitable conductive material, and/or combinations thereof. Though eight metal line layers M1-M8 are discussed with reference to FIG. 1, front-side interconnect structure 140 can have any number of metal line layers M1-M8. The layout of metal lines 144 and vias 146 is exemplary and not limiting and other layout variations of metal lines 144 and vias 146 are within the scope of this disclosure. The number and arrangement of metal lines 144 and vias 146 can be different from the ones shown in FIG. 1. The routings (also referred to as “electrical connections”) between device region 120 and front-side interconnect structure 140 are exemplary and not limiting. There may be routings between device layer 120 and front-side interconnect structure 140 that are not visible in the cross-sectional view of FIG. 1.

In some embodiments, passivation layer 108 can include an oxide layer and a nitride layer. The oxide layer can include silicon oxide (SiO₂) or another suitable oxide-based dielectric material and nitride layer can include silicon nitride (SiN) or another suitable nitride-based dielectric material that can provide moisture control to IC chip 102 during the packaging of IC chip 102. In some embodiments, conductive pads 109 can include aluminum.

A fault detector 150 can be placed under IC chip package 100 to detect faults or defects in IC chip 102. Fault detector 150 can be a component of a fault detection system (not illustrated in FIG. 1) that is configured to detect optical or thermal signals 152 emitted by devices, such as semiconductor devices 124 in device region 120. In some embodiments, fault detector 150 can include a laser voltage probe (LSP) and/or an emission microscope (EMMI) for detecting optical signals and performing device failure analysis. In some embodiments, fault detector 150 can be a camera equipped with an indium antimonide (InSb) detector for detecting microwave signals. In some embodiments, fault detector 150 can be infrared thermo-imaging cameras configured to detect infrared radiation. Due to the presence of conductive lines 114 and 116, signals 152 emitted by semiconductor devices 124 in device region 120 can be undetected by fault detector 150 because signals can propagate through dielectric layers (e.g., dielectric layer 112) and semiconductor layers (e.g., substrate 122), but can be blocked by metal elements (e.g., conductive lines 114 and 116 and/or vias 115 in back-side interconnect structure 110) if present in the signal propagation path between semiconductor devices 124 and fault detector 150. To prevent such signal blockage during fault detection in IC chip 102, a back-side contact region 207 and a back-side interconnect structure 210 (shown in FIG. 2A) with keep-out regions 230 (also referred to as “metal-free regions 230”) can be disposed on back-side of device region 120 instead of back-side contact region 107 and back-side interconnect structure 110.

FIG. 2 is a cross-sectional view of an IC chip package 200 incorporating a back-side contact region 207 and a back-side interconnect structure 210 with keep-out regions 230, according to some embodiments. The discussion of elements in FIGS. 1 and 2A with the same annotations applies to each other, unless mentioned otherwise. IC chip package 200 can include a back-side interconnect structure 210, which includes vias 115 and conductive lines 114 and 116. IC chip package 200 can further include other suitable structures and are not illustrated in FIG. 2A for simplicity. Components in IC chip package 200 are for illustration purposes and are not drawn to scale.

Keep-out regions 230 are regions in a back-side contact region 207 and backside interconnect structure 210 where no conductive lines or vias are formed. Keep-out regions 230 can allow signals 252 emitted by semiconductor devices 124 during the fault detection process to propagate through substrate 122 and the dielectric layers of back-side contact region 207 and backside interconnect structure 210 to fault detector 150. Signals 252 can propagate through dielectric layers (e.g., dielectric layer 112 and dielectric layer of back-side contact region 207) and semiconductor layers (e.g., substrate 122), but can be blocked by metal elements (e.g., metal lines and/or vias in back-side interconnect structure 210) if present in the signal propagation path between the fault detection areas and fault detector 150. Such signal blockage can result in signal detection failure by fault detector 150, which can result in inaccurate device failure analysis of semiconductor devices 124 by the fault detection system. In some embodiments, signals 252 can be optical signals or thermal signals. Similar to back-side contact region 107, back-side contact region 207 can include conductive structures (not shown) in a dielectric layer, but unlike back-side contact region 107, back-side contact region 207 does not include conductive structures in keep-out regions 230 and includes dielectric material of the dielectric layer of back-side contact region 207.

Each of keep-out regions 230 can overlap or be substantially aligned to active areas (e.g., S/D regions 129 and/or gate structures 133) of semiconductor devices 124 corresponding to the output terminals (e.g., output terminals 201A, 202A, and/or 203A) of the standard cell circuits (e.g., standard cell circuits 201, 202, and/or 203) in device region 120. In some embodiments, the output terminals of the standard cell circuits can include gate terminals, S/D terminals, or any suitable terminals of a transistor device. The back-side of active areas of semiconductor devices 124 corresponding to the output terminals of the standard cell circuits can be referred to as “fault detection areas.” Signals 252 emitted from the fault detection areas during the fault detection process can propagate to fault detector 150 through keep-out regions 230 unhindered by any metal elements in back-side contact region 207 and backside interconnect structure 210. In some embodiments, signals 252 can include photon emissions due to electron-hole recombination in S/D region 129 and/or at the junctions between gate structures 133 and S/D regions 129. The intensity of the emitted signals 252 can be indicative of operation status of devices 124. In some embodiments, signals 252 higher than a threshold value can indicate a malfunctioning device in device region 120. Thus, based on signals 252 detected by fault detector 150, any malfunctioning semiconductor devices in the standard cell circuits in device region 120 can be identified, and device failure analysis in device region 120 can be performed by the fault detection system.

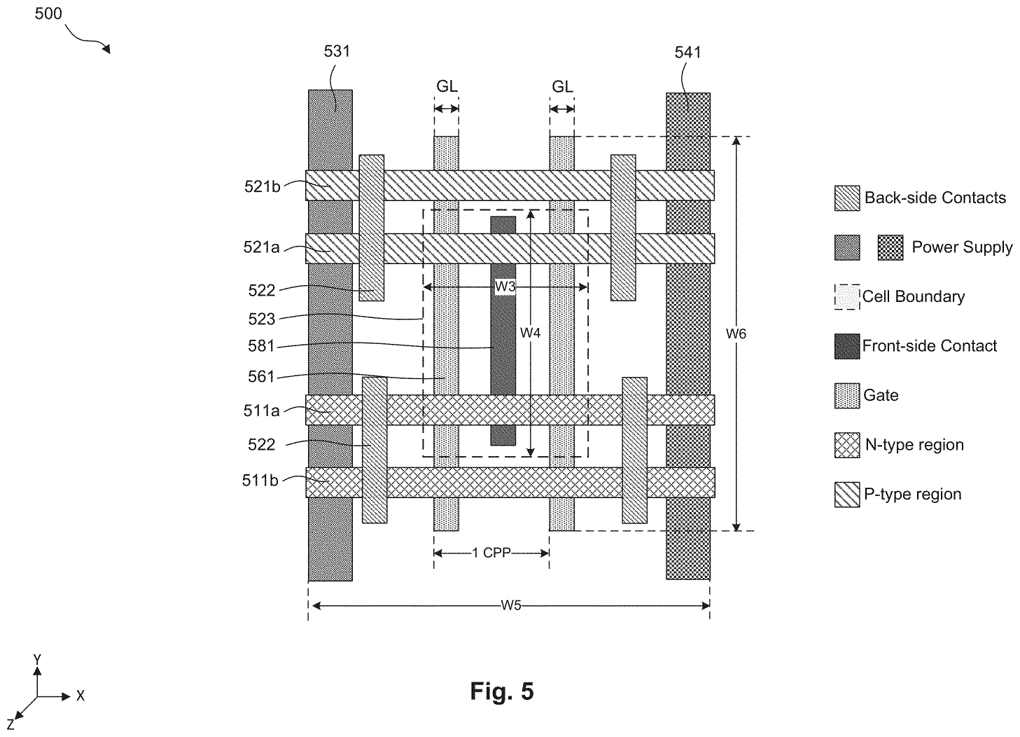

In some embodiments, the boundaries of keep-out regions 230 can be formed based on certain criteria to optimize the detection of signals 252 from the fault detection areas. In some embodiments, forming keep-out regions 230 based on these criteria can allow adequate propagation of signals 252 through substrate 122, back-side contact region 207, and back-side interconnect structure 210 because the signals are less susceptible to interference by metal elements in substrate 122, back-side contact region 207, and/or back-side interconnect structure 210. In some embodiments, keep-out regions 230 can have widths W1 and W2 along a Y-axis, as shown in FIG. 2A. In some embodiments, widths W1-W2 can be substantially equal to or different from each other. In some embodiments, each of widths W1 and W2 can be (i) greater than 1 contacted poly pitch (CPP), (ii) substantially equal to or greater than the sum of a distance between adjacent gate structures along an X-axis and the gate lengths of the adjacent gate lengths, (iii) substantially equal to or greater than the sum of a distance between adjacent active areas (e.g., S/D regions 129) along a Y-axis and the widths of the adjacent active areas (e.g., widths of adjacent S/D regions 129 along a Y-axis), and/or (iv) substantially equal to or greater than a width of the standard cell along a Y-axis. The CPP (shown in FIG. 5; also referred to as “gate pitch”) is defined as a sum of a distance along an X-axis between adjacent gate structures of substantially equal gate lengths (e.g., gate structures 133) and a gate length of one of the adjacent gate structures. The CPP is also defined as a distance along an X-axis between the symmetry lines along a Y-axis of adjacent gate structures of substantially equal gate lengths. In some embodiments, S/D regions 129 can have contact structures (not shown) on their back-side surfaces and facing back-side interconnect structure 210 and each of widths W1 and W2 can be greater than widths of the contact structures along a Y-axis.

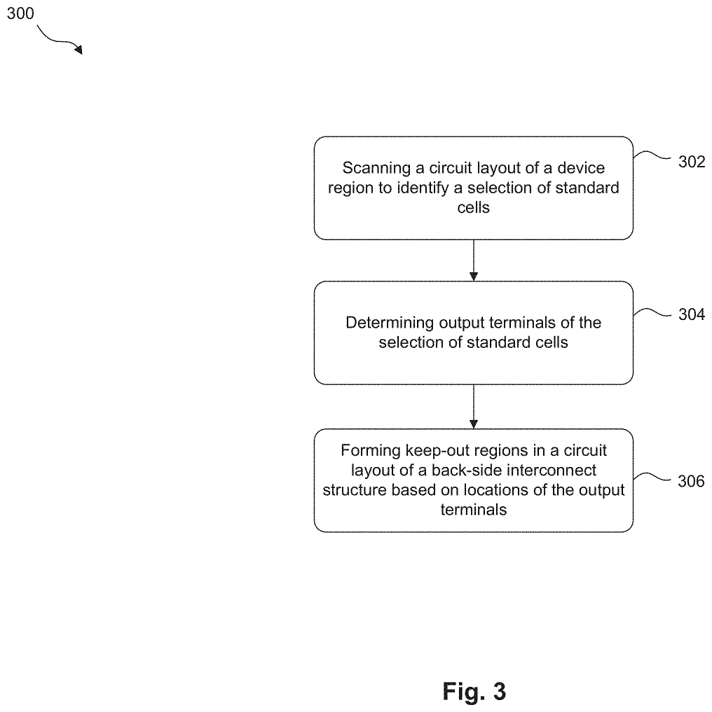

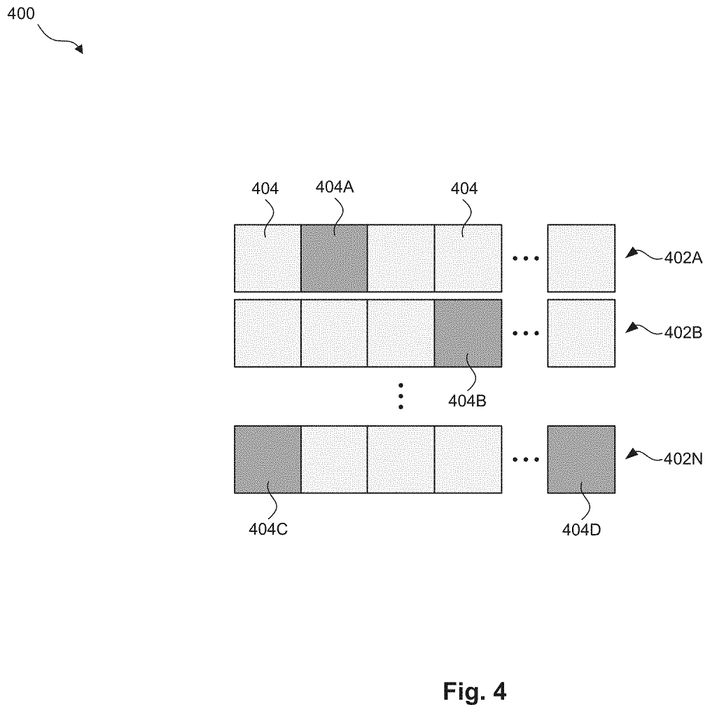

FIG. 3 is a flow diagram of a method 300 for forming keep-out regions and placing conductive lines of a back-side interconnect structure in a circuit layout of a standard cell in an IC chip for an IC chip package, in accordance with some embodiments. In some embodiments, the circuit layout can be for a photolithographic mask layout. In some embodiments, the photolithographic mask layout can be for the fabrication of an IC chip (e.g., IC chip 200) and a back-side interconnect structure (e.g., back-side interconnect structure 210) having keep-out regions (e.g., keep-out regions 230) disposed on the back-side surface of the IC chip. It should be noted that the operations of method 300 can be performed in a different order and/or vary, and method 300 may include more operations that are not described for simplicity. FIGS. 4, 5, 6A, 6B, and 7 are various views of standard cells and metal routing diagrams. In some embodiments, the structures in FIGS. 4, 5, 6A, 6B, and 7 can include various suitable devices or embedded structures that are not illustrated for simplicity. Although processes for forming conductive lines in back-side interconnect structures are described as examples, the formation process can be applied to various suitable semiconductor structures. The described formation processes are exemplary, and alternative processes in accordance with this disclosure may be performed that are not shown in the figures. The discussion of elements in FIGS. 1, 2A-2C, 5, 6A-6C, and 7 with the same annotations applies to each other, unless mentioned otherwise.

At operation 302, a circuit layout of a device region is scanned to determine a selection of standard cells, according to some embodiments of the present disclosure. Referring to FIG. 4, a circuit layout 400 corresponding to a device region of an IC chip can include arrays of standard cells 404 arranged in rows 402A-404N. An example of the device region can be device region 120 of IC chip 200 illustrated in FIG. 2A. Standard cells 404 illustrated in FIG. 4 can include semiconductor devices, such as transistor devices (not illustrated in FIG. 4 for simplicity). In some embodiments, one or more standard cells 404 can represent standard cell circuits 201, 202, or 203. In some embodiments, standard cells 404 can incorporate fin field-effect transistors (finFETs). In some embodiments, standard cells 404 can implement a one-fin layout which includes one p-type finFET and one n-type finFET. In some embodiments, standard cells 404 can implement a two-fin layout which includes two p-type finFETs and two n-type finFETs. Compared to the two-fin layout, the one-fin layout is a more compact unit that provides improved layout flexibility and greater cell density.

An automatic routing and placement (APR) tool can be configured to scan the circuit layout corresponding to the device region. Based on a predetermined set of selection rules, the APR tool can be configured to identify and select a group of standard cells 404 that satisfy the predetermined set of selection rules. In some embodiments, the set of selection rules can include identifying standard cells that contain certain functional units of interest, such as latches, switches, adders, comparators, amplifiers, etc. As an example, a selection of standard cells 404A-404D are identified by the APR tool that contain functional units of interest.

At operation 304, output terminals of the selection of standard cells are determined, according to some embodiments of the present disclosure. An APR tool can be configured to identify output terminals of the selected standard cells. Referring to FIG. 5, a back-side view of an exemplary circuit layout of a two-fin standard cell 500 is illustrated. Standard cell 500 can be one of the selection of standard cells 404A-404D of FIG. 4. Standard cell 500 can include n-type regions 511a and 511b, p-type regions 521a and 521b, back-side metal S/D contacts 522, power supply lines 531 and 541 that are perpendicular to the n-type or p-type regions, gate structures 561, and front-side S/D contact 581. In some embodiments, front-side S/D contact 581 can be an output terminal of standard cell 500. In some embodiments, standard cell 500 can represent standard cell circuits 201, 202, or 203 and front-side S/D contact 581 can represent output terminal 201A, 202A, or 203A shown in FIGS. 2B-2C. In some embodiments, the APR tool can identify output terminals, such as front-side S/D contact 581, which connects to both n-type region 511a and p-type region 521a. In some embodiments, any suitable structure of standard cell 500 can be used as output and/or input terminals.

In some embodiments, n-type regions 511a-511b and p-type regions 521a-521b can represent S/D regions 129 shown in FIG. 2A, front-side S/D contact 581 can represent S/D contact structures 131 shown in FIG. 2A, and gate structures 561 can represent gate structures 133 shown in FIG. 2A. In some embodiments, the fault detection area discussed above with reference to FIG. 2A can be represented by fault detection area 523 in FIG. 5. In some embodiments, fault detection area 523 can include back-side portions of n- and p-type regions 511a and 521a electrically coupled to output terminal (i.e., front-side contact 581) of standard cell 500 and back-side portions of gate structures 561 electrically coupled to n- and p-type regions 511a and 521a. In some embodiments, fault detection area 523 can have a width W3 along an X-axis (i) greater than 1 CPP, (ii) substantially equal to or greater than the sum of a distance between adjacent gate structures 561 along an X-axis and the gate lengths GL of the adjacent gate structures 561, and/or (iii) substantially equal to or smaller than a width W5 of standard cell 500 along an X-axis. In some embodiments, fault detection area 523 can have a width W4 along a Y-axis (i) substantially equal to or greater than the sum of a distance between adjacent active areas (e.g., n- and p-type regions 511a and 521a) along a Y-axis and the widths of the adjacent active areas (e.g., widths of n- and p-type regions 511a and 521a along a Y-axis), and/or (ii) substantially equal to or smaller than a width W6 of standard cell 500 along a Y-axis. Within these ranges of widths W3-W4, signals from fault detection area 523 can be adequately detected by a fault detector, such as fault detector 150, without compromising the size of standard cell 500 and manufacturing cost of the IC chip package incorporating one or more of standard cell 500.

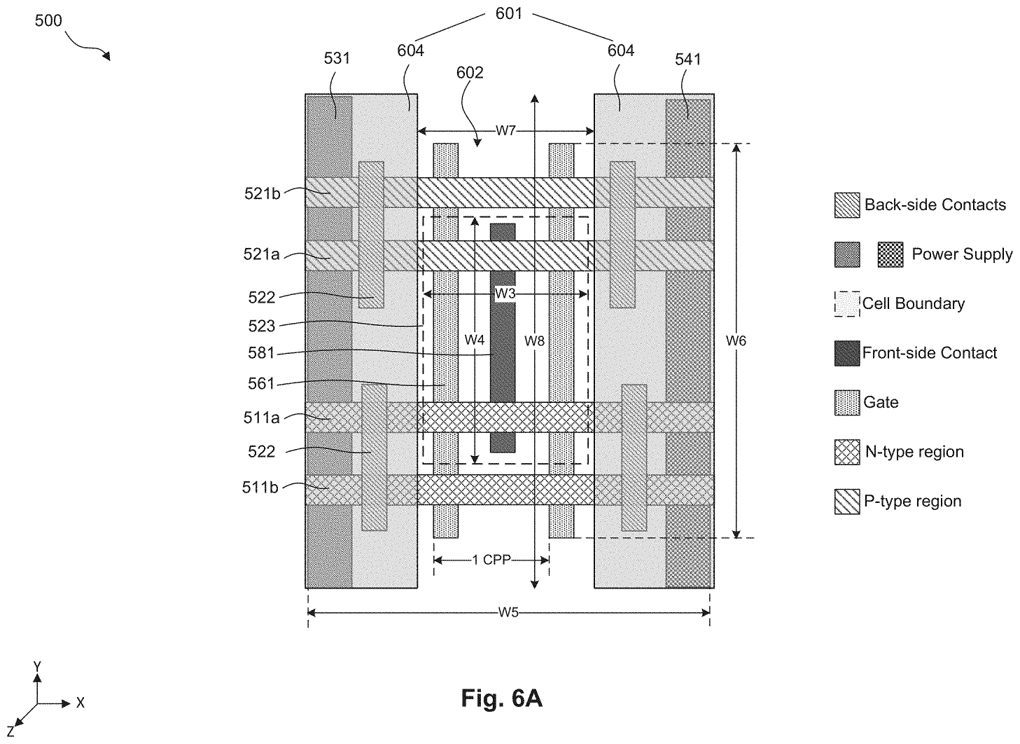

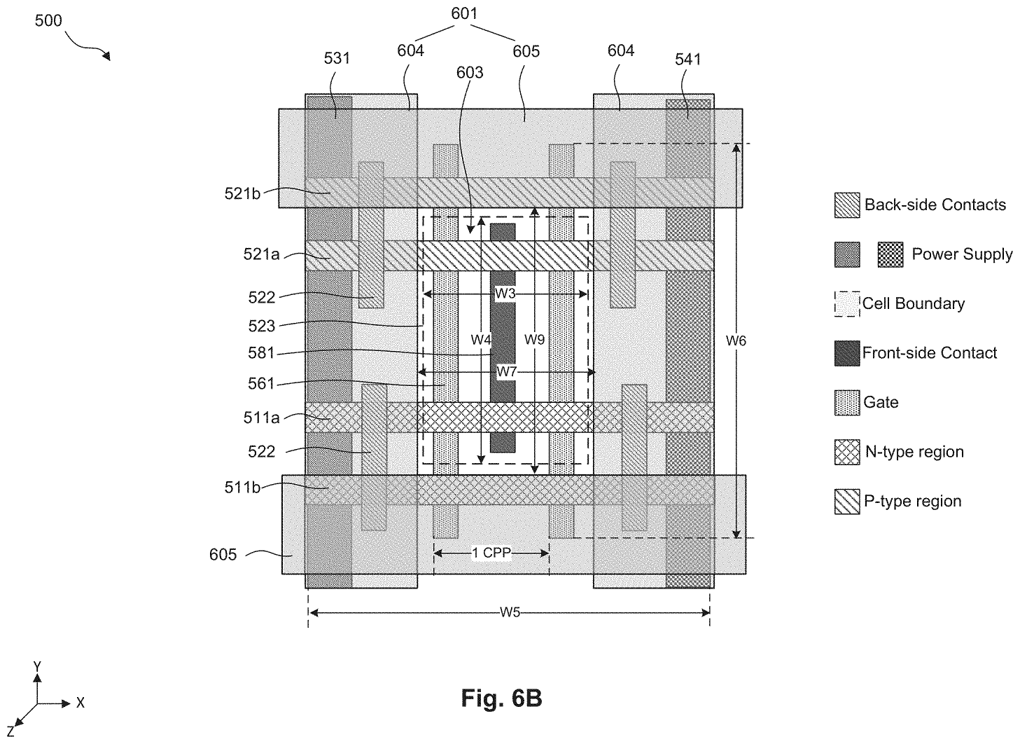

As power is supplied to standard cell 500 through power supply lines 531 and 541 during the fault detection process of an IC chip (e.g., IC chip 200 shown in FIG. 2A), n- and p-type regions 511a and 521a can emit signals (e.g., signals 252 shown in FIG. 2A) that can be detected from fault detection area 523 by fault detector 150. In some embodiments, the signals can include photon emissions due to electron-hole recombination in n- and p-type regions 511a and 521a and/or at the junctions between gate structures 561 and n- and p-type regions 511a and 521a. The intensity of the emitted signals can be indicative of the fabrication yield and operation status of devices (e.g., devices 124 shown in FIG. 2A) within standard cell 500. In some embodiments, a signal higher than a threshold value can indicate a malfunctioning device in standard cell 500. In some embodiments, fault detection area 523 can be substantially aligned to a keep-out region (e.g., keep-out region 230 shown in FIG. 2A), as described in detail below with reference to FIGS. 6A-6B.

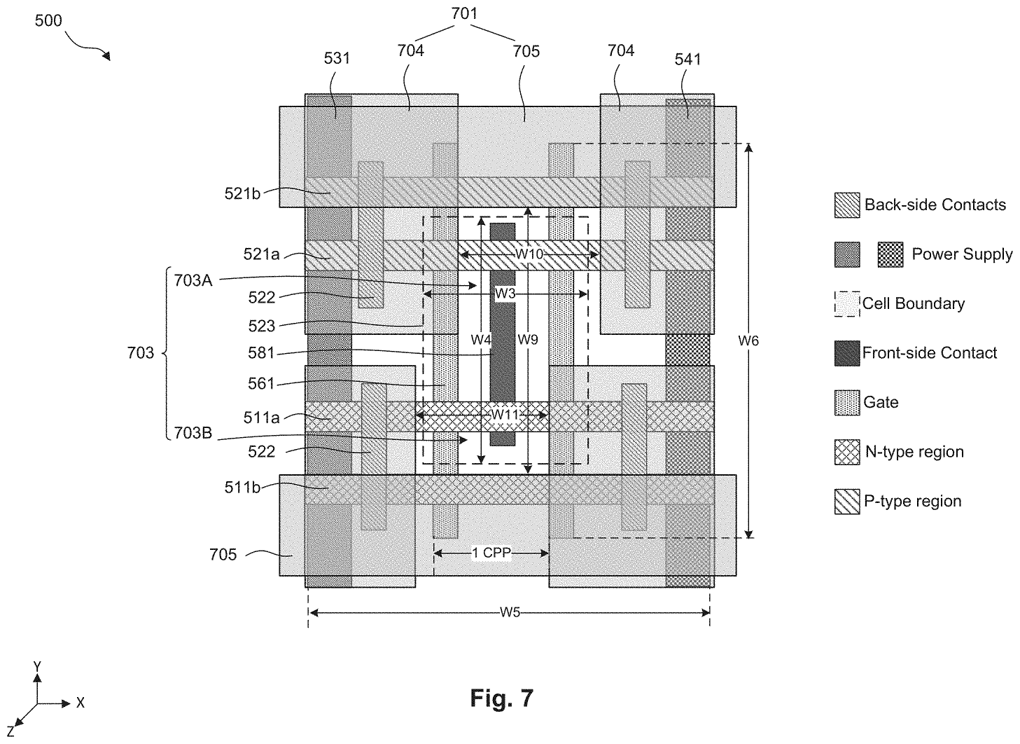

At operation 306, keep-out regions are formed in a circuit layout of a back-side interconnect structure based on locations of the output terminals, according to some embodiments of the present disclosure. FIGS. 6A, 6B, and 7 illustrate various embodiments of circuit layouts of back-side interconnect structures with keep-out regions. Specifically, FIG. 6A illustrates a keep-out region 602 bounded by conductive lines on two sides, FIG. 6B illustrates a keep-out region 603 bounded by conductive lines on four sides and have a substantially rectangular-shaped boundary, and FIG. 7 illustrates a keep-out region 706 with an offset between an upper portion and a lower portion of keep-out region 706. The keep-out regions can have any suitable boundary shapes based on device design and needs. For example, the keep-out regions can have boundaries with a substantially circular shape, a substantially oval shape, or any suitable boundary shapes. In some embodiments, a single keep-out region can be formed in a standard cell. In some embodiments, more than one keep-out region can be formed in a standard cell. The APR tool can be configured to place conductive lines outside the boundary of the keep-out region on each metal layer of the back-side interconnect structure.

Referring to FIG. 6A, a keep-out region 602 is formed in a circuit layout of a back-side interconnect structure 601, according to some embodiments. In some embodiments, keep-out region 602 can represent keep-out region 230 shown in FIG. 2A and back-side interconnect structure 601 can represent back-side interconnect structure 210 illustrated in FIG. 2A. In some embodiments, back-side interconnect structure 601 can include conductive lines 604 substantially parallel to each other in one metal layer of the back-side interconnect structure 601. In some embodiments, conductive lines 604 can represent conductive lines 114 on one of the metal layers shown in FIG. 2A. Conductive lines 604 can be placed outside the boundary of keep-out region 602.

In some embodiments, keep-out region 602 can be substantially aligned with fault detection area 523 to allow substantially unhindered propagation of signals emitted from n- and p-type regions 511a and 512a to a fault detector, such as fault detector 150 illustrated in FIG. 2A. In some embodiments, keep-out region 602 can be formed with a width W7 along an X-axis that is (i) greater than 1 CPP, (ii) substantially equal to or greater than the sum of a distance between adjacent gate structures 561 along an X-axis and the gate lengths GL of the adjacent gate structures 561, (iii) substantially equal to or greater than width W3 of fault detection area 523, and/or (iv) substantially equal to or smaller than width W5 of standard cell 500. In some embodiments, keep-out region 602 can be formed with a width W8 along a Y-axis that is (i) substantially equal to or greater than the sum of a distance between adjacent active areas (e.g., n- and p-type regions 511a and 511a) along a Y-axis and the widths of the adjacent active areas (e.g., widths of n- and p-type regions 511a and 511a along a Y-axis), (ii) substantially equal to or greater than dimension of gate structures 561 along a Y-axis, (iii) substantially equal to or greater than width W4 of fault detection area 523, and/or (iv) substantially equal to or greater than width W6 of standard cell 500. In some embodiments, width W7 can be between about 1.0 and about 1.4 times the CPP. In some embodiments, width W7 can be between about 30 nm and about 90 nm. For example, width W7 can be between about 40 nm and about 70 nm, between about 45 nm and about 65 nm, between about 50 nm and about 60 nm, or any suitable dimensions. Within these ranges of widths W7-W8, keep-out region 602 can allow substantially unhindered propagation of signals from fault detection area 523 to fault detector 150 without compromising the size of back-side interconnect structure 601 and standard cell 500 and manufacturing cost of the IC chip package incorporating back-side interconnect structure 601 and one or more of standard cell 500.

Referring to FIG. 6B, a keep-out region 603 is formed in a circuit layout of back-side interconnect structure 601, according to some embodiments. In some embodiments, keep-out region 603 can represent keep-out region 230 shown in FIG. 2A and back-side interconnect structure 601 can represent back-side interconnect structure 210 illustrated in FIG. 2A. In some embodiments, back-side interconnect structure 601 can include conductive lines 604 in one metal layer and conductive lines 605 substantially parallel to each other in another metal layer of the back-side interconnect structure 601. In some embodiments, conductive lines 604 can be above or below conductive lines 605. In some embodiments, conductive lines 604-605 can represent conductive lines 114 on different metal layers shown in FIG. 2A and can be substantially perpendicular to each other. Conductive lines 604-605 can be placed outside the boundary of keep-out region 603.

In some embodiments, keep-out region 603 can be substantially aligned with fault detection area 523 to allow substantially unhindered propagation of signals emitted from n- and p-type regions 511a and 512a to a fault detector, such as fault detector 150 illustrated in FIG. 2A. In some embodiments, similar to keep-out region 602, keep-out region 603 can have a width W7 along an X-axis. In some embodiments, keep-out region 603 can be formed with a width W9 along a Y-axis that is (i) substantially equal to or greater than the sum of a distance between adjacent active areas (e.g., n- and p-type regions 511a and 511a) along a Y-axis and the widths of the adjacent active areas (e.g., widths of n- and p-type regions 511a and 511a along a Y-axis), (ii) substantially equal to or smaller than dimension of gate structures 561 along a Y-axis, (iii) substantially equal to or greater than width W4 of fault detection area 523, and/or (iv) substantially equal to or smaller than width W6 of standard cell 500. Within these ranges of widths W7 and W9, keep-out region 603 can allow substantially unhindered propagation of signals from fault detection area 523 to fault detector 150 without compromising the size of back-side interconnect structure 601 and standard cell 500 and manufacturing cost of the IC chip package incorporating back-side interconnect structure 601 and one or more of standard cell 500.

Referring to FIG. 7, a keep-out region 703 is formed in a circuit layout of a back-side interconnect structure 701, according to some embodiments. In some embodiments, keep-out region 703 can represent keep-out region 230 shown in FIG. 2A and back-side interconnect structure 701 can represent back-side interconnect structure 210 illustrated in FIG. 2A. In some embodiments, back-side interconnect structure 701 can include conductive lines 704 substantially parallel to each other in one metal layer and conductive lines 705 substantially parallel to each other in another metal layer of the back-side interconnect structure 701. In some embodiments, conductive lines 704 can be above or below conductive lines 705. In some embodiments, conductive lines 704-705 can represent conductive lines 114 on different metal layers shown in FIG. 2A and can be substantially perpendicular to each other. Conductive lines 704-705 can be placed outside the boundary of keep-out region 703.

In some embodiments, keep-out region 703 can include can include a first portion 703A and a second portion 703B. First portion 703A and second portion 703B can each have a substantially rectangular-shaped boundary and have a horizontal offset along an X-axis with respect to each other. First portion 703A can be substantially aligned with first and second sides of fault detection area 523 and misaligned with a third side of fault detection area 523. Second portion 703B can be substantially aligned with third and fourth sides of fault detection area 523 and misaligned with the second side of fault detection area 523. The first and fourth sides of fault detection area 523 are opposite and parallel to each other. The second and third sides of fault detection area 523 are opposite and parallel to each other. In some embodiments, similar to keep-out region 603, keep-out region 703 can have a width W9 along a Y-axis. In some embodiments, first portion 703A can have a width W10 along an X-axis and second portion 703B can have a width W11 along an X-axis. Widths W10-W11 can be substantially equal or different from each other. In some embodiments, each of widths W10 and W11 can be (i) greater than 1 CPP, (ii) substantially equal to or greater than the sum of a distance between adjacent gate structures 561 along an X-axis and the gate lengths GL of the adjacent gate structures 561, (iii) substantially equal to or greater than width W3 of fault detection area 523, and/or (iv) substantially equal to or smaller than width W5 of standard cell 500. Within these ranges of widths W7 and W10-W11, keep-out region 703 can allow substantially unhindered propagation of signals from fault detection area 523 to fault detector 150 without compromising the size of back-side interconnect structure 701 and standard cell 500 and manufacturing cost of the IC chip package incorporating back-side interconnect structure 701 and one or more of standard cell 500.

In some embodiments, the APR tool can be configured to place other conductive lines on or below conductive lines 604, 605, 704, and 705 on other metal layers of back-side interconnect structures 601 and 701 excluding keep-out regions 602, 603 and 703. In some embodiments, conductive lines formed in other metal layers (not illustrated in FIGS. 6A, 6B, and 7) of back-side interconnect structures 601 and 701 can be substantially perpendicular or parallel to conductive lines 604, 605, 704, and 705. In some embodiments, the APR is further configured to place vias (e.g., vias 115 shown in FIG. 2A) in back-side interconnect structures 601 and 701 excluding keep-out regions 602, 603, and 703.

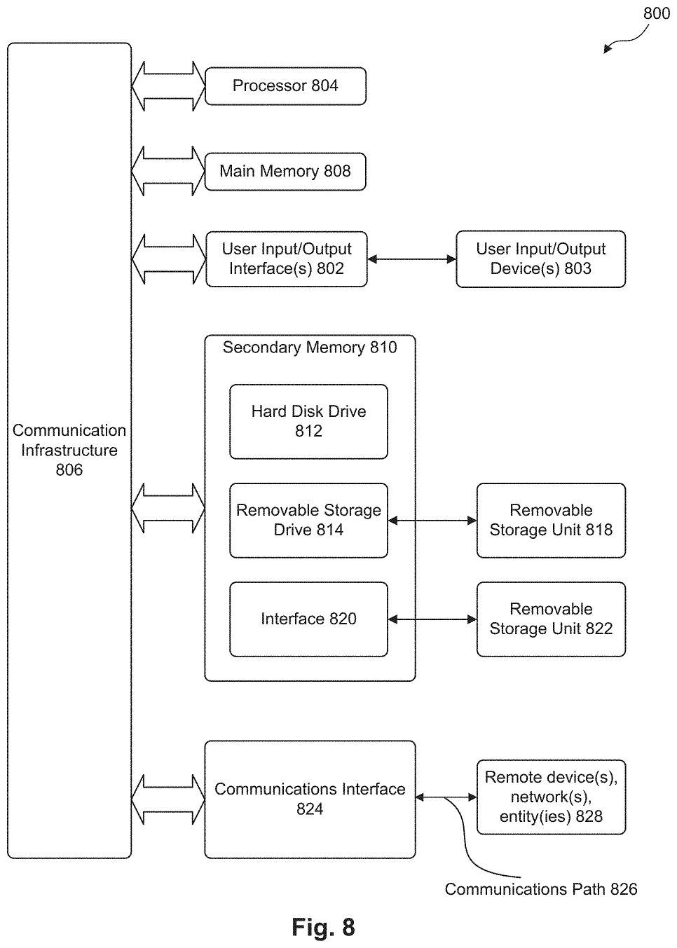

FIG. 8 is an illustration of an example computer system 800 in which various embodiments of the present disclosure can be implemented, according to some embodiments. Computer system 800 can be any computer capable of performing the functions and operations described herein. For example, and without limitation, computer system 800 can be capable of selecting standard cells, determining output terminals of the selected standard cells, and forming keep-out region. In some embodiments, computer system 800 can be an EDA tool. Computer system 800 can be used, for example, to execute one or more operations in method 300, which describes an example method for forming keep-out regions in a circuit layout area.

Computer system 800 includes one or more processors (also called central processing units, or CPUs), such as a processor 804. Processor 804 is connected to a communication infrastructure or bus 806. Computer system 800 also includes input/output device(s) 803, such as monitors, keyboards, pointing devices, etc., that communicate with communication infrastructure or bus 806 through input/output interface(s) 802. An EDA tool can receive instructions to implement functions and operations described herein—e.g., method 300 of FIG. 3—via input/output device(s) 803. Computer system 800 also includes a main or primary memory 808, such as random access memory (RAM). Main memory 808 can include one or more levels of cache. Main memory 808 has stored therein control logic (e.g., computer software) and/or data. In some embodiments, the control logic (e.g., computer software) and/or data can include one or more of the operations described above with respect to method 300 of FIG. 3. For example, main memory 808 can include a non-transitory computer-readable medium having instructions stored thereon that, when executed by computer system 800, causes computer system 800 to perform operations, such as forming keep-out regions and placing and/or rerouting conductive lines.

Computer system 800 can also include one or more secondary storage devices or memory 810. Secondary memory 810 can include, for example, a hard disk drive 812 and/or a removable storage device or drive 814. Removable storage drive 814 can be a floppy disk drive, a magnetic tape drive, a compact disk drive, an optical storage device, tape backup device, and/or any other storage device/drive.

Removable storage drive 814 can interact with a removable storage unit 818. Removable storage unit 818 includes a computer usable or readable storage device having stored thereon computer software (control logic) and/or data. Removable storage unit 818 can be a floppy disk, magnetic tape, compact disk, DVD, optical storage disk, and/any other computer data storage device. Removable storage drive 814 reads from and/or writes to removable storage unit 818 in a well-known manner.

According to some embodiments, secondary memory 810 can include other means, instrumentalities or other approaches for allowing computer programs and/or other instructions and/or data to be accessed by computer system 800. Such means, instrumentalities or other approaches can include, for example, a removable storage unit 822 and an interface 820. Examples of the removable storage unit 822 and the interface 820 can include a program cartridge and cartridge interface (such as that found in video game devices), a removable memory chip (such as an EPROM or PROM) and associated socket, a memory stick and USB port, a memory card and associated memory card slot, and/or any other removable storage unit and associated interface. In some embodiments, secondary memory 810, removable storage unit 818, and/or removable storage unit 822 can include one or more of the operations described above with respect to method 300 of FIG. 3.

Computer system 800 can further include a communication or network interface 824. Communication interface 824 enables computer system 800 to communicate and interact with any combination of remote devices, remote networks, remote entities, etc. (individually and collectively referenced by reference number 828). For example, communication interface 824 can allow computer system 800 to communicate with remote devices 828 over communications path 826, which can be wired and/or wireless, and which can include any combination of LANs, WANs, the Internet, etc. Control logic and/or data can be transmitted to and from computer system 800 via communication path 826.

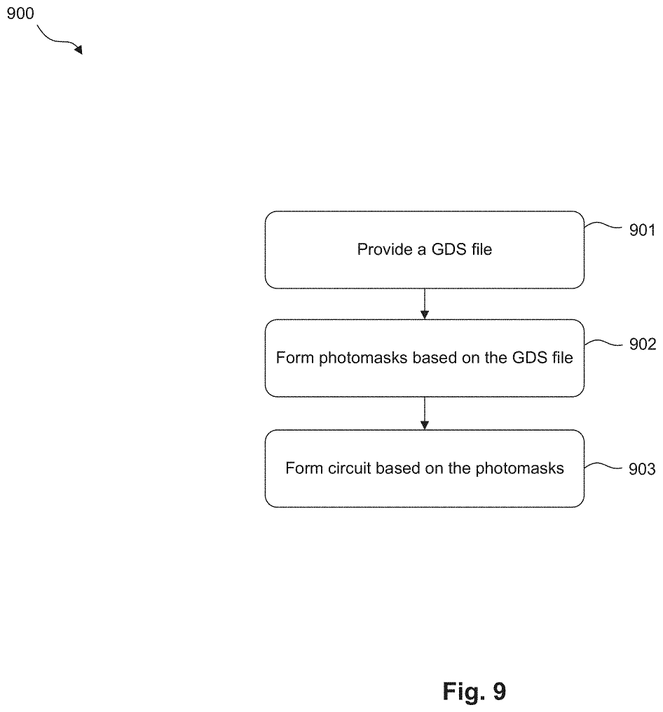

The operations in the preceding embodiments can be implemented in a wide variety of configurations and architectures. Therefore, some or all of the operations in the preceding embodiments—e.g., method 300 of FIG. 3 and method 900 of FIG. 9 (described below)—can be performed in hardware, in software or both. In some embodiments, a tangible apparatus or article of manufacture comprising a tangible computer useable or readable medium having control logic (software) stored thereon is also referred to herein as “a computer program product” or “a program storage device.” This includes, but is not limited to, computer system 800, main memory 808, secondary memory 810 and removable storage units 818 and 822, as well as tangible articles of manufacture embodying any combination of the foregoing. Such control logic, when executed by one or more data processing devices (such as computer system 800), causes such data processing devices to operate as described herein. In some embodiments, computer system 800 is installed with software to perform operations in the manufacturing of photolithographic masks and circuits, as illustrated in method 800 of FIG. 9 (described below). In some embodiments, computer system 800 includes hardware/equipment for the manufacturing of photolithographic masks and circuit fabrication. For example, the hardware/equipment can be connected to or be part of remote devices 828 (remote device(s), network(s), entity(ies)) of computer system 800.

FIG. 9 is an illustration of an exemplary method 900 for circuit fabrication, according to some embodiments. In some embodiments, operations/steps of method 900 can be performed in a different order. Variations of method 900 should also be within the scope of the present disclosure.

In operation 901, a GDS file is provided. The GDS file can be generated by an EDA tool and include standard cell structures optimized based on the present disclosure. The operation depicted in operation 901 can be performed by, for example, an EDA tool that operates on a computer system, such as computer system 800 described above.

In operation 902, photolithographic masks are formed based on the GDS file. In some embodiments, the GDS file provided in operation 901 is taken to a tape-out operation to generate photolithographic masks for fabricating one or more integrated circuits. In some embodiments, a circuit layout included in the GDS file can be read and transferred onto a quartz or glass substrate to form opaque patterns that correspond to the circuit layout. The opaque patterns can be made of, for example, chromium or other suitable metals. Operation 902 can be performed by a photolithographic mask manufacturer, where the circuit layout is read using a suitable software tool (e.g., an EDA tool) and the circuit layout is transferred onto a substrate using a suitable printing/deposition tool. The photolithographic masks reflect the circuit layout/features included in the GDS file.

In operation 903, one or more circuits are formed based on the photolithographic masks generated in operation 902. In some embodiments, the photolithographic masks are used to form patterns/structures of the circuit contained in the GDS file. In some embodiments, various fabrication tools (e.g., photolithography equipment, deposition equipment, and etching equipment) are used to form features of the one or more circuits.

Various embodiments described in the present disclosure are directed to back-side interconnect structures (e.g., back-side interconnect structures 210, 601, and 701) in IC chip packages (e.g., IC chip package 200) and methods for forming the same. In some embodiments, the back-side interconnect structure can include metal lines (e.g., conductive lines 114), metal vias (e.g., conductive vias 115), and metal-free regions (e.g., metal-free regions 230, 602, 603, and 703). The metal-free regions can be formed substantially aligned with output terminals (e.g., output terminals 201A-203A) of standard cell circuits (e.g., standard cell circuits 201-203) in the IC chip (e.g., IC chip 102 of FIG. 2A) to prevent optical signals (e.g., signals 252) from being blocked by metal elements in the back-side interconnect structures during the fault detection in the IC chip. In some embodiments, an automatic placement and routing (APR) tool can be configured to scan standard cell circuit layouts (e.g., standard cell layouts 500) of the IC chip to identify active areas corresponding to output terminals of the standard cell circuits and design metal-free regions in the metal layout of the back-side interconnect structure. According to one or more routing and placement rules, no conductive line of the back-side interconnect structure is formed in the metal-free regions which in turn allows signals emitted by the one or more active areas to be transmitted through the back-side interconnect structure and detected by sensors of the fault detection system.

In some embodiments, a structure includes a substrate with first and second surfaces, a device layer disposed on the first surface of the substrate, having a fault detection area on a back-side surface of the device layer configured to emit a signal that is indicative of a presence or an absence of a defect in the device layer, a first interconnect structure disposed on a front-side of the device layer, and a second interconnect structure disposed on the second surface of the substrate, having a metal-free region aligned with the fault detection area and a first metal layer having first and second conductive lines disposed substantially parallel to each other. First and second sidewalls of the first and second conductive lines, respectively, facing each other are substantially aligned with first and second sides of the fault detection area.

In some embodiments, a structure includes a substrate with first and second surfaces, first and second source/drain regions disposed on the first surface of the substrate, first and second gate structures disposed on the first surface of the substrate and adjacent to the source/drain regions, a first interconnect structure disposed on the first and second source/drain regions, and a second interconnect structure disposed on the second surface of the substrate, having a metal-free region and a first metal layer having first and second conductive lines disposed substantially parallel to each other. First and second sidewalls of the first and second conductive lines, respectively, facing each other form first and second sides of the metal-free region.

In some embodiments, a method includes scanning an integrated circuit (IC) layout to identify a standard cell, determining a source/drain (S/D) region of the standard cell that forms an output terminal of the standard cell, and forming a metal-free region in a metal layer layout of an interconnect structure on a back-side of the standard cell and substantially aligned with a back-side surface area of the S/D region.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

1. A structure, comprising:
a substrate with first and second sides;
a device layer disposed on the first side of the substrate, comprising a fault detection area on a back-side surface of the device layer configured to emit a signal that is indicative of a presence or an absence of a defect in the device layer;
a first interconnect structure disposed on a front-side of the device layer; and
a second interconnect structure disposed on the second side of the substrate, comprising:
a metal-free region aligned with the fault detection area; and
a first metal layer comprising first and second conductive lines, wherein first and second sidewalls of the first and second conductive lines, respectively, facing each other are substantially aligned with first and second sides of the fault detection area.

2. The structure of claim 1, wherein the second interconnect structure further comprises a second metal layer comprising third and fourth conductive lines disposed substantially parallel to each other and substantially perpendicular to the first and second conductive lines, respectively, and
wherein first and second sidewalls of the third and fourth conductive lines, respectively, facing each other are substantially aligned with third and fourth sides of the fault detection area.

3. The structure of claim 1, wherein the second interconnect structure further comprises a second metal layer comprising third and fourth conductive lines disposed substantially parallel to each other and substantially perpendicular to the first and second conductive lines, respectively,
wherein first sidewalls of the first and third conductive lines substantially perpendicular to each other are substantially aligned with the first side and a third side of the fault detection area, and
wherein the first and third sides of the fault detection area are substantially perpendicular to each other.

4. The structure of claim 1, wherein the metal-free region comprises a width substantially equal to or greater than a sum of a distance between adjacent gate structures in the device layer and gate lengths of the adjacent gate structures.

5. The structure of claim 1, wherein the metal-free region comprises a width substantially equal to or greater than a sum of a distance between adjacent source/drain regions in the device layer and widths of the adjacent source/drain regions.

6. The structure of claim 1, wherein the metal-free region comprises a width substantially equal to or greater than a width of the fault detection area.

7. The structure of claim 1, wherein the metal-free region comprises a width substantially equal to or smaller than a width of a standard cell in the device layer.

8. The structure of claim 1, wherein the metal-free region comprises first and second portions misaligned with each other.

9. The structure of claim 1, wherein the metal-free region comprises a rectangular shape.

10. The structure of claim 1, wherein the fault detection area comprises source/drain regions in the device layer.

11. A structure, comprising:
a substrate with first and second sides;
first and second source/drain regions disposed on the first side of the substrate;
first and second gate structures disposed on the first side of the substrate and adjacent to the first and second source/drain regions;
a first interconnect structure disposed on the first and second source/drain regions; and
a second interconnect structure disposed on the second side of the substrate, comprising:
a metal-free region; and
a first metal layer comprising first and second conductive lines, wherein first and second sidewalls of the first and second conductive lines, respectively, facing each other form first and second sides of the metal-free region.

12. The structure of claim 11, wherein the second interconnect structure further comprises a second metal layer comprising third and fourth conductive lines disposed substantially parallel to each other and substantially perpendicular to the first and second conductive lines, respectively, and
wherein first and second sidewalls of the third and fourth conductive lines, respectively, facing each other form third and fourth sides of the metal-free region.

13. The structure of claim 11, wherein the second interconnect structure further comprises a second metal layer comprising third and fourth conductive lines disposed substantially parallel to each other and substantially perpendicular to the first and second conductive lines, respectively,
wherein first sidewalls of the first and third conductive lines substantially perpendicular to each other form the first side and a third side of the metal-free region, and
wherein the first and third sides of the metal-free region are substantially perpendicular to each other.

14. The structure of claim 11, wherein the metal-free region comprises a width substantially equal to or greater than a sum of a distance between the first and second gate structures and gate lengths of the first and second gate structures.

15. The structure of claim 11, wherein the metal-free region comprises a width substantially equal to or greater than a sum of a distance between the first and second source/drain regions and widths of the first and second source/drain regions.

16. The structure of claim 11, wherein the metal-free region comprises first and second portions misaligned with each other.

17. A method, comprising:
scanning an integrated circuit (IC) layout to identify a standard cell;
determining a source/drain (S/D) region of the standard cell that forms an output terminal of the standard cell; and
forming a metal-free region in a metal layer layout of an interconnect structure on a back-side of the standard cell and substantially aligned with a back-side surface area of the S/D region.

18. The method of claim 17, wherein forming the metal-free region comprises placing first and second conductive lines in a first metal layer of the interconnect structure such that first and second sidewalls of the first and second conductive lines, respectively, facing each other form first and second sides of the metal-free region.

19. The method of claim 18, wherein forming the metal-free region comprises placing third and fourth conductive lines in a second metal layer of the interconnect structure substantially parallel to each other and substantially perpendicular to the first and second conductive lines, respectively, such that first and second sidewalls of the third and fourth conductive lines, respectively, facing each other form third and fourth sides of the metal-free region.

20. The method of claim 17, further comprising detecting signals from the back-side surface area of the S/D region.
